(19) United States
(12) Patent Application Publication
(10) Pub. No.: US 2014/0284404 A1
(43) Pub. Date: Sep. 25, 2014

(54) CHEMICAL VAPOUR DEPOSITION INJECTOR

(71) Applicant: ASM TECHNOLOGY SINGAPORE PTE LTD., Singapore (SG)

(72) Inventors: Teng Hock KUAH, Singapore (SG); Hongbo LIU, Singapore (SG); Jiuan WEI, Singapore (SG); Wentao WANG, Singapore (SG); Jingsheng CHEN, Singapore (SG); Jiapei DING, Singapore (SG); Ravindra RAGHAVENDRA, Singapore (SG); Bubesh Babu JOTHEESWARAN, Singapore (SG); Meer Saiful HASSAN, Singapore (SG)

(73) Assignee: ASM Technology Singapore Pte Ltd., Singapore (SG)

(21) Appl. No.: 13/847,628

(22) Filed: Mar. 20, 2013

(51) Int. Cl. C23C 16/455

(52) U.S. Cl. CPC C23C 16/45565
USPC 239/408

(57) ABSTRACT

Disclosed is a chemical vapour deposition injector 100, comprising a gas injector body 104 having a plurality of holes for directing a first gas from a first gas plenum into respective first gas channels of the gas injector body, each first gas channel extending in a first direction and arranged to branch into separate flow paths; a plurality of discrete first conduits, each first conduit being arranged to connect to a respective one of the discrete flow paths for carrying the first gas to a reaction chamber; a second gas channel for directing a second gas from a second gas plenum into the gas injector body, the second gas channel having a longitudinal axis which extends in a second direction transverse to the first direction; and a plurality of discrete second conduits coupled to the second gas channel and arranged to carry the second gas from the second gas channel to the reactor chamber; wherein at least some of the discrete second conduits are arranged between the discrete first conduits.

### BACKGROUND AND FIELD

This invention relates to a chemical vapour deposition injector.

Chemical vapour deposition (CVD) reactors, or more particularly metal organic chemical deposition (MOCVD) reactors are used in semiconductor industry to produce compound semiconductor devices such as laser diodes, light emitting diodes (LEDs) etc. Such reactors include a reaction chamber where precursors react with each other under certain temperature and pressure conditions to form a homogeneous gas mixture which is deposited as a thin film on a substrate placed in the reaction chamber.

For MOCVD, the two precursors are typically TMGa (or TMIn) and NH3 The reactor includes a gas injector for introducing the precursors into the reaction chamber. A first challenge in the design of the gas injector is to prevent pre-reaction between the two precursors. This is because if they are allowed to mix before entering the reaction chamber, the two precursors would mix and react with each other to form particles which condense on walls of the reactor (which would be colder than the precursors). Such condensation is a waste of the precursors and may also degrade the reactor.

Thus, the gas injector should deliver the two precursors separately until the two precursors enter the reaction chamber, where they are allowed to mix.

A second challenge is to achieve uniform flow rates for the two precursors as the gases leave the gas injector's outlets. As the two precursors are injected into the reaction chamber, uniformity of the flow rates of the two precursors from the gas injector's outlets is critical to achieving a preferred gas flow pattern.

There have been proposed reactors to address the above two challenges. However, most address one but not the other challenges and for those that attempt to address both of these challenges, none can meet these challenges in a cost effective way or they are difficult to maintain.

### SUMMARY

In a first aspect of the invention, there is provided a chemical vapour deposition gas injector, comprising a gas injector body having
an array of holes for directing a first gas from a first gas plenum into respective first gas channels of the gas injector body, each first gas channel extending in a first direction and arranged to branch into separate flow paths;
a plurality of discrete first conduits, each first conduit being arranged to connect to a respective one of the discrete flow paths for carrying the first gas to a reaction chamber;
a second gas channel for directing a second gas from a second gas plenum into the gas injector body, the second gas channel having a longitudinal axis which extends in a second direction transverse to the first direction; and
a plurality of discrete second conduits coupled to the second gas channel and arranged to carry the second gas from the second gas channel to the reactor chamber; and
wherein at least some of the discrete second conduits are arranged between the discrete first conduits.

An advantage of the described embodiment is that this achieves a more uniform flow rate for the gases and much easier to manufacture. Further, the arrangement ensures that the two gases do not mix until the gases reach the reaction chamber.

Preferably, the gas injector body may comprise a semi-annular channel for receiving the first gas from the first gas channel, the semi-annular channel being arranged to split the first gas into the separate flow paths.

Each of the discrete first and second conduits may include a flow development portion for reducing pressure of the first and second gas respectively as the gases exits to the reaction chamber. The development portion may have an opening for receiving the first or second gas and a discharge opening for discharging the first or second gas to the reaction chamber, wherein the discharge opening is larger than the first opening. The flow development portion is particularly advantageous to reduce turbulence of the gas flow.

The gas injector body may further comprise the first plenum and the second plenum. The gas injector body may further comprise a first gas distribution channel for receiving the first gas from a first gas inlet and the first gas distribution channel is arranged adjacent to and around the first gas plenum. The gas injector body may further comprise a first plenum wall separating the first gas distribution channel and the first gas plenum, and with the first plenum wall comprising a first continuous gap to enable the first gas to diffuse from the first gas distribution channel to the first gas plenum. In this way, this improves the circulation gas flow. The gap may be about 1 mm for optimum results but it should be appreciated that this dimension may be varied.

The gas injector may also comprise a second gas distribution channel for receiving the second gas from a second gas inlet, and the second gas distribution channel is arranged adjacent to and around the second gas plenum. The gas injector may further comprise a second plenum wall separating the second gas distribution channel and the second gas plenum, and with the second plenum wall comprising a second continuous gap to enable the second gas to diffuse from the second gas distribution channel to the second gas plenum. In this way, circulation of the second gas is improved. The gap may be about 1 mm for optimum results but it should be appreciated that other dimensions are possible too.

Preferably, centre-to-centre distance between one of the second conduits and an immediately adjacent first conduit may be about 5 mm. Preferably, centre-to-centre distance between two immediately adjacent second conduits may be about 5 mm.

Preferably, the gas injector body further comprises a heat exchanging fluid distribution element for controlling temperature of the first and second gases. The heat exchanging fluid distribution element may comprise a series of elongate heat exchanging fluid channels through which at least some of the first and second conduits pass. The series of elongate heat exchanging fluid channels may be arranged along a second longitudinal axis which transverses the longitudinal axis of the second gas channels.

Preferably, the first direction, the longitudinal axis and the second longitudinal axis may be orthogonal to each other.

Preferably, the gas injector body may be a unitary body.

In a second aspect, there is provided a chemical vapour deposition reactor comprising the chemical vapour gas injector of the above aspects.

It should be appreciated that features relating to one aspect may also be applicable to the other aspects.

### BRIEF DESCRIPTION OF THE DRAWINGS

An example of the invention will now be described with reference to the accompanying drawings, in which:

FIG. 1 is a perspective view of a chemical vapour deposition (CVD) reactor, with part of the reactor omitted to show parts of first and second gas input; third input for heat exchanging fluid and delivery members of a gas injector;

FIG. 2 is a perspective cross-sectional view of the CVD reactor of FIG. 1 to show the first gas input and delivery member of the gas injector more clearly;

FIG. 3 is a 2-dimensional view of the CVD reactor of FIG. 2;

FIG. 4 is a perspective view of the CVD reactor of FIG. 1, with certain portions removed, to show flow path of a first precursor gas through part of the first input and delivery member;

FIG. 5 is an enlarged view of portion A of FIG. 3;

FIG. 6 is an enlarged view of portion B of FIG. 3;

FIG. 7 is a perspective view of the CVD reactor of FIG. 1, with certain portions removed, to show flow path of a second precursor gas through part of the second gas input and delivery member;

FIG. 8 is a perspective view of the CVD reactor of FIG. 1, with certain portions removed, to show flow path of a heat exchanging fluid through parts of the third fluid input and delivery member; and

FIG. 9 shows flow paths of first and second precursors using FIG. 2;

### DETAILED DESCRIPTION OF PREFERRED EMBODIMENT

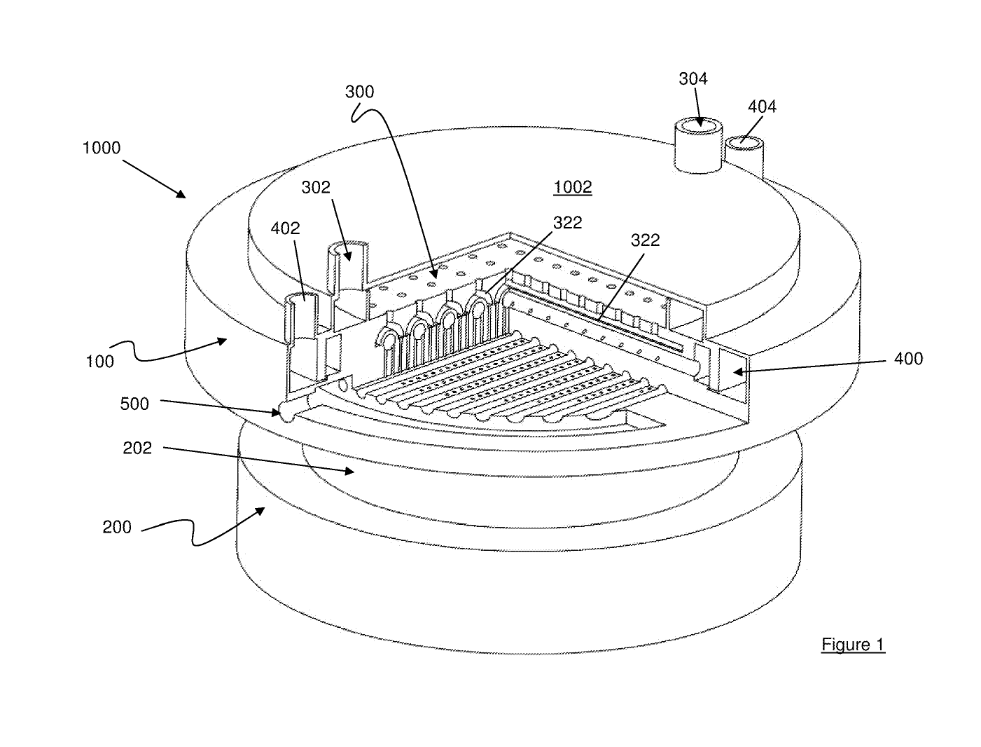

FIG. 1 is a perspective view of a chemical vapour deposition (CVD) reactor 1000 which comprises a gas injector 100 and a deposition compartment 200, which includes a reaction chamber 202. In FIG. 1, part of the reactor 1000 is omitted to show first, second and third fluid input and delivery members 300,400,500 of the gas injector 100.

The first and second gas input and delivery members 300,400 are arranged to deliver and channel a first precursor gas and a second precursors respectively to the reaction chamber 202 and the third fluid input and delivery member 500 is arranged to deliver a heat exchanging fluid for controlling temperature of the first and second gas input and delivery members 300,400.

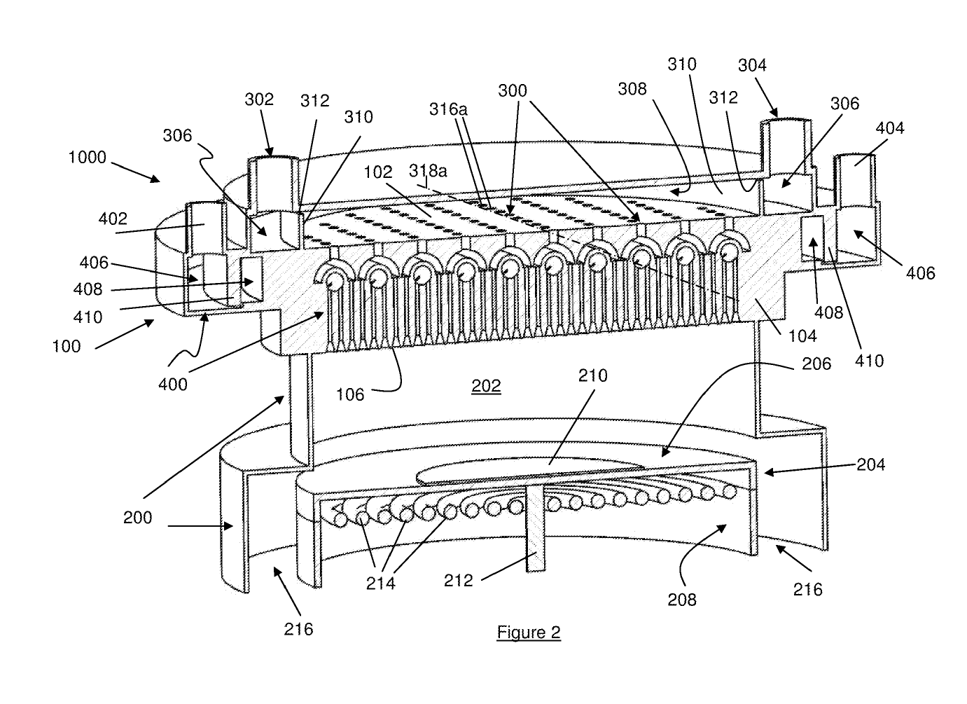

FIG. 2 is a cross-sectional perspective view of the CVD reactor 1000 to show the first and second gas input delivery members 300,400 and the deposition compartment 200. The reactor 1000 further includes a substrate support assembly 204 located within the deposition chamber 200 and below the reaction chamber 202. The substrate support assembly 204 includes a rotatable susceptor 206 above a liner 208. The rotatable susceptor 206 is arranged to support a wafer or substrate 210 and the substrate support assembly 204 also includes a rotating shaft 212 for rotating the rotatable susceptor 206 and a heater comprising an arrangement of heater filaments 214 for heating the rotatable susceptor 206 (and thus, the substrate 210) for example by induction. The deposition compartment 200 further includes an exhaust 216 arranged around the perimeter of the substrate support assembly 204.

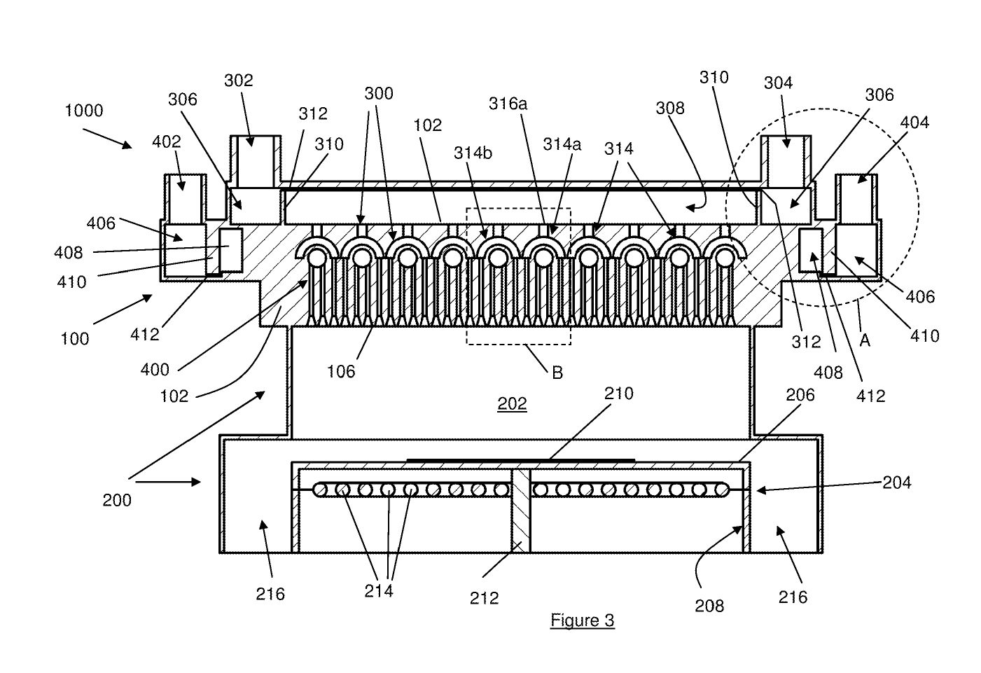

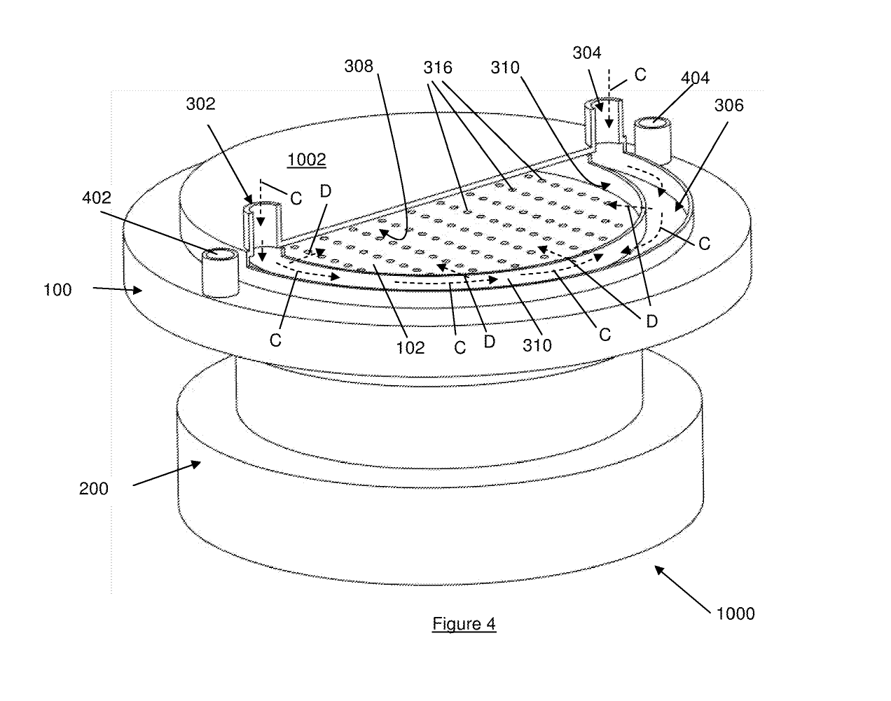

FIG. 3 is a 2-dimensional view of the cross-sectional perspective view of the CVD reactor 1000. Referring to FIGS. 2 and 3, the first gas input and delivery member 300 includes two first gas inlets 302,304, a first gas distribution channel 306, a first gas plenum 308 and a first plenum circumferential wall 310 which is arranged between the first gas distribution channel 306 and the first gas plenum 308. The two first gas inlets 302,304 are about 16 mm in diameter and are connected to a first precursor gas source (not shown) for channeling a first precursor gas, such as gallium (Ga), into the first gas distribution channel 306. The first gas distribution channel 306 is about 22 mm wide by 16 mm in height and the first gas distribution channel 306 is arranged as a continuous loop around the first gas plenum 308, separated by the first plenum circumferential wall 310, and this is shown more clearly in FIG. 4. The first gas plenum 308 includes a space to be filled by the first precursor gas and arranged between a cover 1002 of the reactor 1000, top surface 102 of the injector 100 and the first plenum circumferential wall 310.

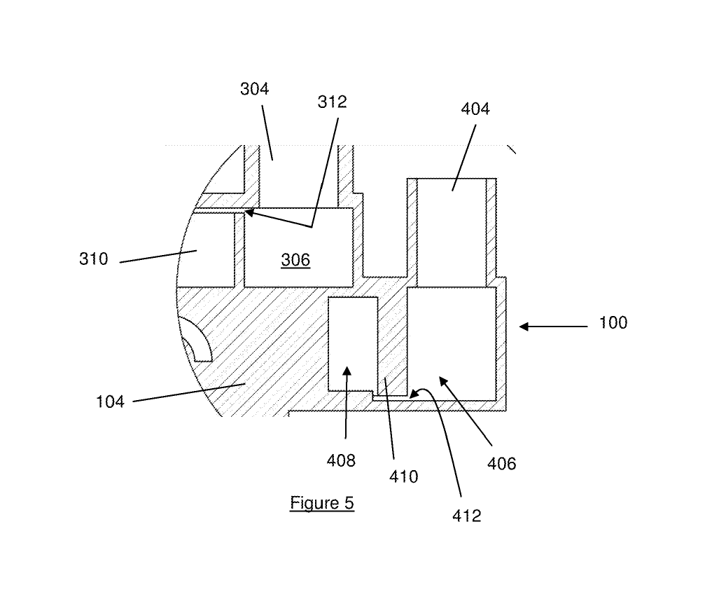

The first plenum circumferential wall 310 has a first flow restrictor 312 which is a small continuous gap of about 1 mm that separates the top edge of the first plenum circumferential wall 310 and the cover 1002 of the reactor 1000, and FIG. 5 shows the first flow restrictor 312 more clearly. In other words, the first flow restrictor 312 runs the entire distance of the continuous loop formed by the first gas distribution channel 306. When the first precursor gas is introduced into the two first gas inlets 302,304, the first precursor gas travels along a path or distance, as shown by arrows C in FIG. 4, defined by the first gas distribution channel 306 and does not immediately flow to the first plenum 308 due to the presence of the first plenum circumferential wall 310. Instead, due to the presence of the first flow restrictor 312, as the first precursor gas travels along the first gas distribution channel 306 (or circulates along the continuous loop), some of the first precursor gas is diffused or drawn into the first gas plenum 308 via the first flow restrictor (as shown by arrows D). With this arrangement, this achieves a more uniform gas flow rate in an angular direction for the first precursor gas to fill the first plenum 308.

The gas injector 100 includes a unitary injector body 104 bounded by the top surface 102 and a bottom surface 106 which is contiguous with the reaction chamber 202 and the unitary injector body 104 has a general disc shape.

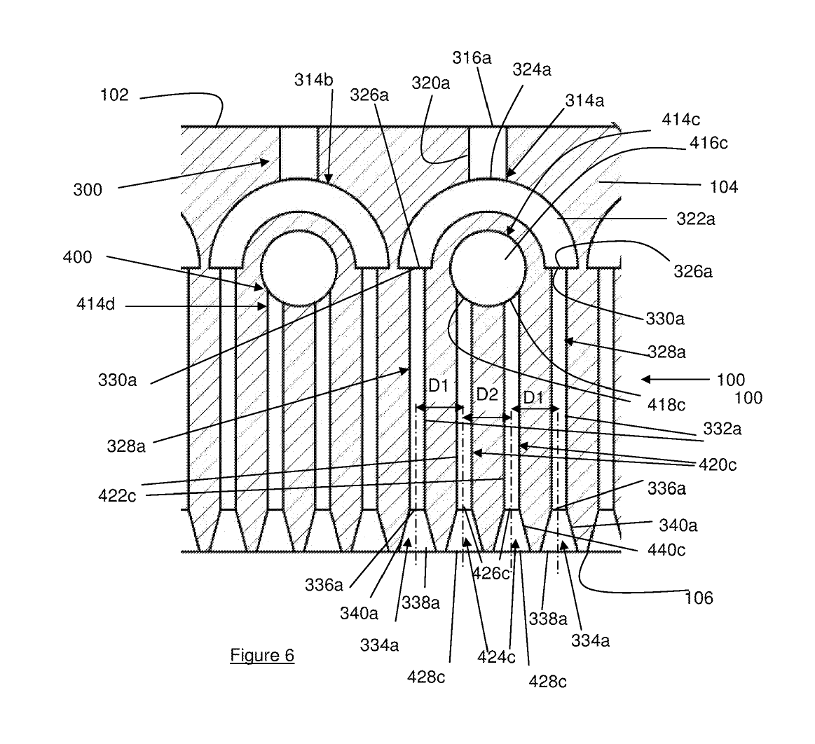

Referring to FIG. 3, the first gas input and delivery member 300 further includes a plurality of first gas delivery elements 314 arranged within the unitary injector body 104. Since each of the first gas delivery elements 314 are identical, only one of the first gas delivery elements 314 will be described with reference to FIG. 6, which is an enlarged view of portion B of FIG. 3 which shows the fifth and sixth first gas delivery elements 314a,314b. The fifth first gas delivery element 314a will be used for the detailed description and for ease of explanation, parts relating to the fifth first gas delivery element will include a suffix “a” (and for the sixth first gas delivery element, suffix is “b”) and when the references are used without the suffix, this means that the references are used to refer parts of the first gas delivery elements 314 in general and not only to the fifth one 314a.

The fifth first gas delivery element 314a includes a row of holes 316a (see FIGS. 2-3, and FIG. 4 shows the holes 316 in general) regularly spaced apart and arranged linearly along a longitudinal axis 318a of the injector body 104. It should be appreciated that the row of holes 316a are disposed on the top surface 102 of the injector body 104. The fifth first gas delivery element 314a further includes a plurality of first gas channels 320a with each first gas channel in fluid communication with corresponding holes 316a. In other words, the plurality of first gas channels 320a are also regularly spaced in a same manner as the plurality of holes 316a and the first gas channels 320a are also arranged linearly along the longitudinal axis 318a. It should also be appreciated that the plurality of holes 316a may be arranged in an array format that comprises one or more rows of the holes 316a and/or one or more columns of the holes 316a.

Each of the first gas channels 320a extends into the injector body 104 in a first direction and is configured to branch into separate flow paths and in this embodiment, this is achieved by an elongate, semi-annular channel 322a which extends continuously along the longitudinal axis 318a (see also FIG. 1, which shows a generally semi-annular channel 322). The semi-annular channel 322a has a number of gas inlets 324a (at apex of the “arc” of the channel 322a) and pairs of gas outlets 326a (which are disposed at ends of the “arc” of the channel 322a). Each of the gas inlets 324a are coupled to respective first gas channels 320a and thus, gas flowing through each first gas channels 320a would split into two different flow paths due to the semi-annular channel 322a and the gas would follow through respective pairs of gas outlets 326a. In other words, one first gas channel 320a is associated with one pair of the gas outlets 326a.

The fifth first gas delivery element 314a further includes a plurality of discrete first conduits 328a with pairs of the first conduits 328a having their inlets 330a coupled to respective pairs of the gas outlets 326a i.e. one inlet 330a of one first conduit 328a to one gas outlet 326a. Each of the first conduits 328a has a main portion 332a of about 1.6 mm in diameter which connects the inlet 330a to a flow development portion 334a. The flow development portion 334a includes a first opening 336a, a first gas discharge opening 338a and a first conduit tapered section 340a. The first opening 336a is coupled to the main portion 332a of the first conduit 328a and has the same diameter as the main portion 332a. However, the first gas discharge opening 338a has a larger diameter than the first opening 336a and which is about 4 mm and this arrangement, together with the tapered section 340a, improves gas flow since it reduces pressure and creates less turbulence in the gas flow.

It should be apparent that the first gas discharge opening 338a are disposed on the bottom surface 106 of the gas injector body 104 and thus, discharges the first gas to the reaction chamber 202.

As shown in FIG. 3, the gas injector 100 also includes a second gas input and delivery member 400 for delivering a second precursor gas to the reaction chamber 202. The second gas input and delivery member 400 includes two second gas inlets 402,404, a second gas distribution channel 406, a second gas plenum 408 and a second plenum circumferential wall 410 which is arranged between the second gas distribution channel 406 and the second gas plenum 408.

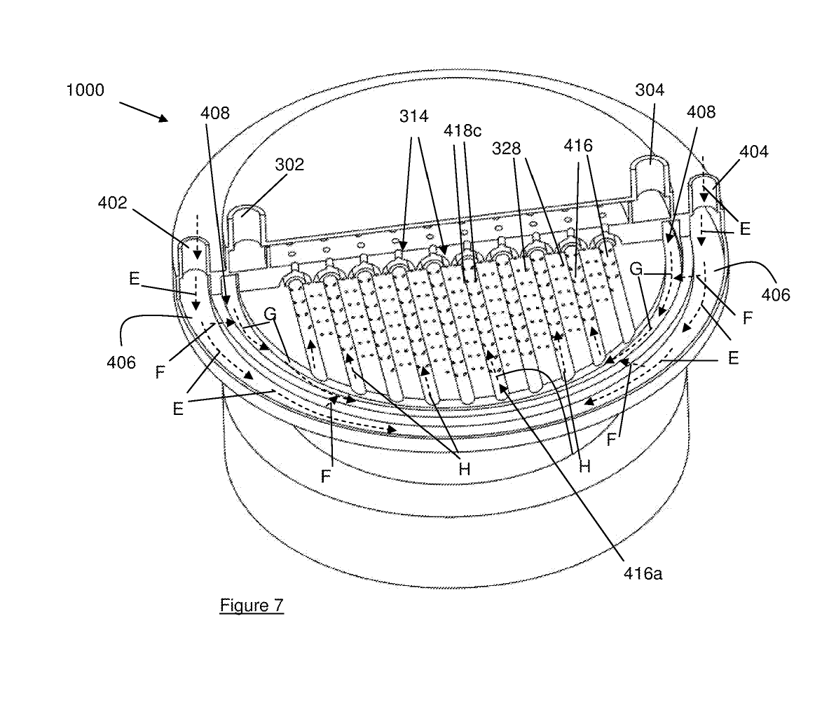

The two second gas inlets 402,404 are about 14 mm in diameter and are connected to a second precursor gas source (not shown) for channeling a second precursor gas, such as Nitrogen into the second gas distribution channel 406. The second gas distribution channel 406 is about 18 mm wide by 23 mm in height and the second gas distribution channel 406 is arranged also as a continuous loop around the second gas plenum 408, separated by the second plenum circumferential wall 410, and this is shown more clearly in FIG. 7. Unlike the first plenum 308, the second gas plenum 408 is a longitudinal arcuate channel to be filled by the second precursor gas and is separated from the second gas distribution channel 406 by the second plenum circumferential wall 410. The second plenum circumferential wall 410 has a second flow restrictor 412 which is a small continuous gap of about 1 mm between the bottom edge of the second plenum circumferential wall 410 and the base of the second gas distribution channel 406, and FIG. 5 shows the second flow restrictor 412 more clearly. In other words, the second flow restrictor 412 runs the entire distance of the continuous loop formed by the second gas distribution channel 406. It should be appreciated that the second flow restrictor 412 is arranged at the “bottom” end of the second plenum circumferential wall 410 if the first flow restrictor 312 is considered to be arranged at the “top” end of the first plenum circumferential wall 310.

Referring to FIG. 3, the second gas input and delivery member 400 further includes a plurality of second gas delivery elements 414 arranged within the unitary injector body 104. Since each of the second gas delivery elements 414 are identical, only one of the second gas delivery elements 414 will be described with reference again to FIG. 6 which shows the fifth and sixth second gas delivery elements 414c,414d. The fifth second gas delivery element 414c will be used for the detailed description and for ease of explanation, parts relating to the fifth second gas delivery element will include a suffix “c” (and for the sixth gas delivery element, suffix is “d”) and when the references are used without the suffix, this means that the references are used to refer parts of the second gas delivery elements 414 in general and not only to the fifth one 414c.

The fifth second gas delivery element 414c includes an elongate tubular channel 416c (see also FIG. 7) which extends along the longitudinal axis 318a of the injector body 104 and transverse to the first direction of the first gas channels 320. Ends of the elongate tubular channel 416c are in fluid communication with the second plenum 408 which means that the second gas from the second plenum 408 would flow into the tubular channel 416c. This also means that the second plenum 408 surrounds the elongate tubular channel 416c or that the elongate tubular channel 416c is disposed in the second plenum 408 which saves space.

The tubular channel 416c further includes a plurality of second gas openings 418c which are connected to respective downstream second conduits 420c. Each of the second conduits 420c includes a main portion 422c of about 1.6 mm diameter and a flow development portion 424c for reducing the pressure of the second gas as it exits to the reaction chamber 202 and in this way, creates less turbulence. The flow development portion 424c includes a second opening 426c, a second gas discharge opening 428c and a second conduit tapered section 440c. The second opening 426c is coupled to one of the second gas openings 418c and has the same diameter as the main portion 422c. However, the second gas discharge opening 428c has a larger diameter than the second opening 426c and which is about 4 mm and this arrangement, together with the second conduit tapered section 440c, improves gas flow since it reduces pressure and creates less turbulence in the gas flow.

It should be apparent that, in this embodiment, the second conduits 420c are arranged in two rows along the longitudinal axis 318a and between the first conduits 328. Distance D2 between corresponding pairs of second conduits 420c and D1, between one of the second conduits 420c and an immediately adjacent first conduit 328a has been strategically selected and in this embodiment, D1 and D2 are both about 5 mm (measured between centre to centre) as shown in FIG. 6.

The second gas discharge opening 428c is disposed on the bottom surface 106 of the gas injector body 104 and thus, discharges the second gas to the reaction chamber 202. It may be appreciated that due to the arrangement of the first gas delivery element 314 and the second gas delivery element 414 makes it possible to group each of the first and second gas delivery element 314,414 as sets or groups. In other words, one first gas delivery element 314 may be grouped with one second gas delivery element 414 to form a set which may be called a gas distribution element. It should also be appreciated that for one gas distribution element, the second conduits 420c (or rows of the second conduits) are arranged between the first conduits 328a (or rows of the first conduits), although this may not be the case for the extreme gas distribution elements—see FIG. 3.

When the second precursor gas is introduced into the two second gas inlets 402,404, the second precursor gas travels along a path or distance, as shown by arrows E, defined by the second gas distribution channel 406 and also does not immediately flow to the second plenum 408 due to the presence of the second plenum circumferential wall 410. However, due to the presence of the second flow restrictor 412, as the second precursor gas travels along the second gas distribution channel 406, some of the second precursor gas is diffused or drawn into the second gas plenum 408 via the second flow restrictor 412 (see arrows F). With this arrangement, this also achieves a more uniform gas flow rate in an angular direction for the second precursor gas to fill the second plenum 408, and since the second plenum 408 is arranged as a continuous loop, the second precursor gas also circulates along the continuous loop (as shown by arrows G) until the second precursor gas is drawn into the tubular channel 416a (or generally 416 for all the tubular channels) as shown by arrow H of FIG. 7. The second precursor gas is next drawn into the second conduits 420c and eventually discharges into the reaction chamber 202.

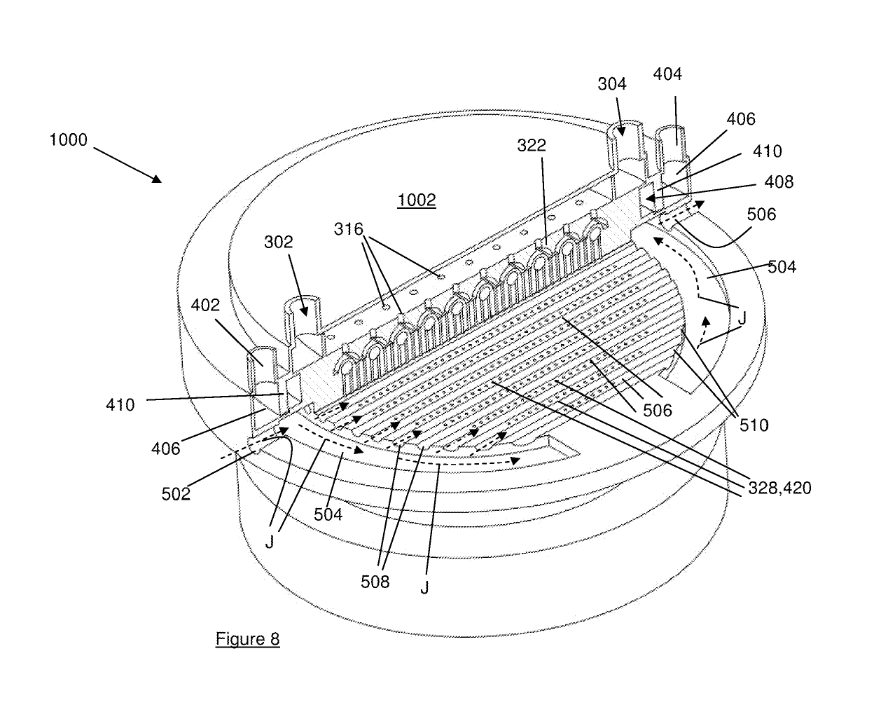

In FIG. 8 the third fluid input and delivery member 500 is arranged to deliver a heat exchanging fluid for controlling temperature of the first and second gas input and delivery members 300,400. The third fluid input and delivery member 500 includes a heat exchanging fluid inlet 502, a heat exchanging fluid distribution channel 504, a series of heat exchanging fluid tubular channels 506, and a heat exchanging fluid outlet 506.

The heat exchanging fluid inlet 502 and the heat exchanging fluid outlet 506 are each about 10 mm in diameter and the heat exchanging fluid inlet 502 is connected to a heat exchanging fluid source (not shown) for channeling a heat exchanging fluid into the injector body 104 for controlling temperature of the first and second precursors.

After the heat exchanging fluid inlet 502, the heat exchanging fluid travels along heat exchanging fluid distribution channel 504 as shown by arrows J and is drawn into the heat exchanging fluid tubular channels 506 via inlets 508 of the heat exchanging fluid tubular channels 506 with outlets 510 of the heat exchanging fluid tubular channels 506 discharging the heat exchanging fluid back to the heat exchanging fluid distribution channel 504 and eventually flowing out of the injector body 104 via the heat exchanging fluid outlet 506. Each heat exchanging fluid tubular channel 506 transverses the elongate tubular channels 416 of the second input and delivery member 400 (or that the heat exchanging fluid tubular channels 506 are orthogonal to the longitudinal axis 318a, although on different planes). Specifically, the first conduits 328 of the first gas delivery element 314 and the second conduits 420 of the second gas delivery element 414 passes orthogonally through the heat exchanging fluid tubular channels 506. In this way, as the first and second precursors flow respectively through the first and second conduits 328,420, they are cooled by the heat exchanging fluid flowing through the heat exchanging fluid tubular channels 506.

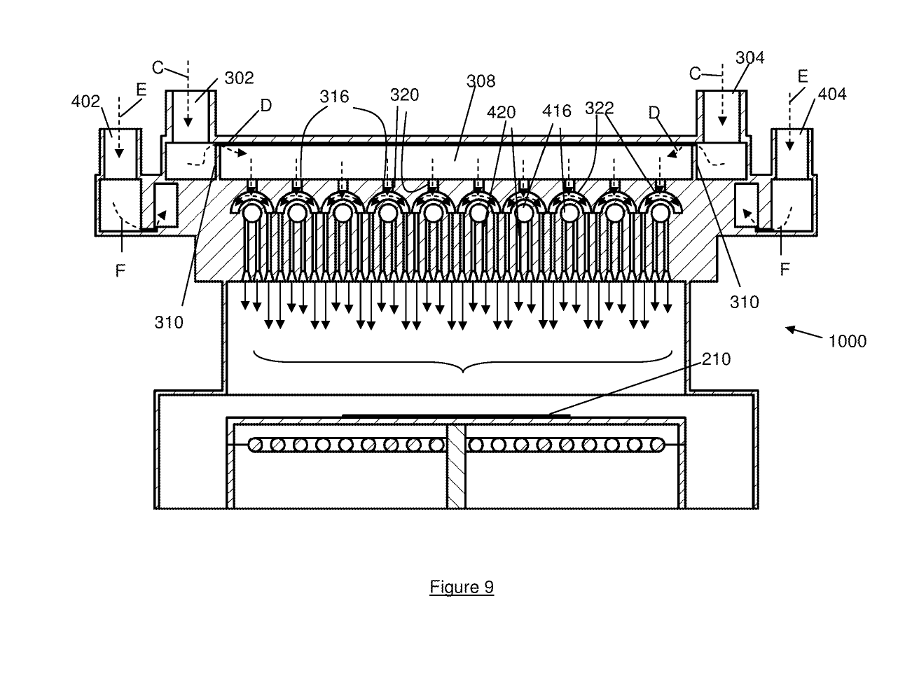

Flow paths of the first and second precursors will now be described with reference to Figures, and in particular, FIG. 9. When the first precursor gas is introduced into the two first gas inlets 302,304 as shown by arrows C, the first precursor gas travels along the first gas distribution channel 306 and gradually the first precursor gas is drawn into the first plenum 308 via the first flow restrictor 312 as shown by arrows D. When the first precursor gas is in the first plenum 308, the first precursor gas is drawn into respective holes 316, the gas channels 320 and then spreads out into two separate paths due to the semi-annular channel 322 and eventually to the first conduits 328.

When the second precursor gas is introduced into the two second gas inlets 402,404, as shown by arrows E, the second precursor gas travels along the second gas distribution channel 406 and gradually the second precursor gas is drawn into the second plenum 408 via the second flow restrictor 412 as shown by arrows F. At the second plenum 408, the second precursor gas is drawn into respective elongate tubular channels 416 and then into the second conduits 420.

When the first precursor gas and the second precursor gas is flowing through the first and second conduits respectively, heat exchanging fluid is passed through the heat exchanging fluid tubular channels 506 which cools the first and second precursors. Eventually, the first and second precursors are discharged out of the injection body 104 and into the reaction chamber 202 via the flow development portions 334,242.

When the first and second precursors are discharged from the injection body and into the reaction chamber 202, this is when the two precursors are allowed to mix with each other to deposit a thin film on the substrate 210.

It should be apparent that at the bottom surface of the 106 of the injector body 104, the outlets of the first and second gas delivery members 300,400 are an array of distinct and separate openings (in this embodiment, they are circular openings) for discharging the first and second precursors into the reaction chamber 202.

Based on the proposed arrangement of the injector 100 and the reactor 1000, it is much easier to manufacture the injector 100. This also makes it a cost effective solution for high volume manufacturing. The injector 100 and reactor 1000 are also easier to maintain and may result in higher production yield. It is also possible to achieve a uniform flow rate for the precursors into the reaction chamber 202 and this may achieve a uniform growth rate for the substrates.

The described embodiments should not be construed as limitative. For example, the dimensions indicated in the embodiment are typical values for a 7×2″ (7×50.8 mm) CVD reactor and for illustrative purposes only. Needless to say, the dimensions may be varied depending on size of the reactor and application etc. Further, the semi-annular channel 322 may not be annular and other shapes are possible as long as the flow paths of the first precursor has is split into separate flow paths. Similarly, the tubular channels 416 and the heat exchanging fluid tubular channels 506 may not be tubular and other shapes, such as a square cross-section rather than circular might be possible, although not preferred.

The described embodiment uses a CVD reactor as an example, but it should be apparent that this invention may also be used for specific types of CVD reactors such as metal organic chemical deposition (MOCVD) reactors. Further, the gas injector 100 may not have the flow development portions 334,424, just preferred to have these.

Having now fully described the invention, it should be apparent to one of ordinary skill in the art that many modifications can be made hereto without departing from the scope as claimed. For instance, although the injector body 104 has been described as a unitary body, it should be appreciated that the first and second gas input and delivery members 300, 400 may also be separate channels for delivery of the first and second precursors to the reaction chamber 202. Although it has been described that the injector body 104 comprises the heat exchanging fluid distribution element input and delivery member 500, it should also be appreciated that such an input and delivery member may also be omitted.

1. A chemical vapour deposition gas injector, comprising
a gas injector body having
a plurality of holes for directing a first gas from a first gas plenum into respective first gas channels of the gas injector body, each first gas channel extending in a first direction and arranged to branch into separate flow paths;
a plurality of discrete first conduits, each first conduit being arranged to connect to a respective one of the discrete flow paths for carrying the first gas to a reaction chamber;
a second gas channel for directing a second gas from a second gas plenum into the gas injector body, the second gas channel having a longitudinal axis which extends in a second direction transverse to the first direction; and
a plurality of discrete second conduits coupled to the second gas channel and arranged to carry the second gas from the second gas channel to the reactor chamber;
wherein at least some of the discrete second conduits are arranged between the discrete first conduits.

2. A chemical vapour gas injector according to claim 1, wherein the gas injector body comprises a semi-annular channel for receiving the first gas from the first gas channel, the semi-annular channel being arranged to split the first gas into the separate flow paths.

3. A chemical vapour gas injector according to claim 1, wherein each of the discrete first and second conduits include a flow development portion for the first and second gases respectively.

4. A chemical vapour gas injector according to claim 3, wherein the flow development portion has an opening for receiving the first or second gas and a discharge opening for discharging the first or second gas to the reaction chamber, wherein the discharge opening is larger than the first opening.

5. A chemical vapour gas injector according to claim 1, wherein the gas injector body further comprises the first plenum and the second plenum.

6. A chemical vapour gas injector according to claim 5, wherein the gas injector body further comprises a first gas distribution channel for receiving the first gas from a first gas inlet; the first gas distribution channel arranged adjacent to and around the first gas plenum.

7. A chemical vapour gas injector according to claim 6, wherein the gas injector body further comprises a first plenum wall separating the first gas distribution channel and the first gas plenum, the first plenum wall comprising a first continuous gap to enable the first gas to diffuse from the first gas distribution channel to the first gas plenum.

8. A chemical vapour gas injector according to claim 7, wherein the gap is about 1 mm.

9. A chemical vapour gas injector according to claim 5, wherein the gas injector body further comprises a second gas distribution channel for receiving the second gas from a second gas inlet; the second gas distribution channel arranged adjacent to and around the second gas plenum.

10. A chemical vapour gas injector according to claim 9, wherein the gas injector body further comprises a second plenum wall separating the second gas distribution channel and the second gas plenum, the second plenum wall comprising a second continuous gap to enable the second gas to diffuse from the second gas distribution channel to the second gas plenum.

11. A chemical vapour gas injector according to claim 10, wherein the gap is about 1 mm.

12. A chemical vapour gas injector according to claim 1, wherein centre-to-centre distance between one of the second conduits and an immediately adjacent first conduit is about 5 mm.

13. A chemical vapour gas injector according to claim 1, wherein centre-to-centre distance between two immediately adjacent second conduits is about 5 mm.

14. A chemical vapour gas injector according to claim 1, wherein the gas injector body further comprises a heat exchanging fluid distribution element for controlling temperature of the first and second gases.

15. A chemical vapour gas injector according to claim 14, wherein the heat exchanging fluid distribution element comprises a series of elongate heat exchanging fluid channels through which at least some of the first and second conduits pass.

16. A chemical vapour gas injector according to claim 15, wherein the series of elongate heat exchanging fluid channels is arranged along a second longitudinal axis which transverses the longitudinal axis of the second gas channels.

17. A chemical vapour gas injector according to claim 16, wherein the first directions, the longitudinal axis and the second longitudinal axis are orthogonal to each other.

18. A chemical vapour gas injector according to claim 1, wherein the gas injector body is a unitary gas injector body.

19. A chemical vapour deposition reactor comprising the chemical vapour gas injector of claim 1.
